(19) United States
(12) Patent Application Publication
(10) Pub. No.: US 2026/0082544 A1
(43) Pub. Date: Mar. 19, 2026

(54) SEMICONDUCTOR DEVICE

(71) Applicant: Kioxia Corporation, Tokyo (JP)

(72) Inventors: Masaya TODA, Yokkaichi Mie (JP); Kazuhiro MATSUO, Kuwana Mie (JP); Ha HOANG, Yokkaichi Mie (JP)

(73) Assignee: Kioxia Corporation, Tokyo (JP)

(21) Appl. No.: 19/074,224

(22) Filed: Mar. 7, 2025

(30) Foreign Application Priority Data
Sep. 18, 2024 (JP) 2024-161126

(51) Int. Cl. H10B 12/00

(52) U.S. Cl. CPC H10B 12/315; H10B 12/05

(57) ABSTRACT

According to one embodiment, a semiconductor device includes: a first electrode; a second electrode which is in contact with an upper surface of the first electrode; a third electrode provided above the second electrode; an oxide semiconductor which extends in a first direction from the second electrode toward the third electrode; a first conductor provided next to the oxide semiconductor; and a first insulating film provided between the first conductor and the oxide semiconductor, wherein: the first insulating film includes a first region and a second region, the second region being sandwiched between the first region and the oxide semiconductor; and a concentration of nitrogen in the first region is higher than a concentration of nitrogen in the second region.

### CROSS-REFERENCE TO RELATED APPLICATION

This application is based upon and claims the benefit of priority from Japanese Patent Application No. 2024-161126, filed Sep. 18, 2024, the entire contents of which are incorporated herein by reference.

### FIELD

Embodiments described herein relate generally to a semiconductor device.

### BACKGROUND

A semiconductor device using a capacitor and a transistor is known.

### BRIEF DESCRIPTION OF THE DRAWINGS

FIG. 1 is a block diagram showing an example of a configuration of a memory system including a semiconductor device according to an embodiment.

FIG. 2 is a circuit diagram showing an example of a circuit configuration of a memory cell array included in the semiconductor device according to the embodiment.

FIG. 3 is a plan view showing an example of a planar layout of the memory cell array included in the semiconductor device according to the embodiment.

FIG. 4 is a sectional view taken along line IV-IV of FIG. 3 and showing an example of a sectional structure of the memory cell array included in the semiconductor device according to the embodiment.

FIG. 5 is a sectional view taken along line V-V of FIG. 3 and showing an example of a sectional structure of the memory cell array included in the semiconductor device according to the embodiment.

FIG. 6 is a sectional view illustrating an example of a structure of a gate insulating film of a transistor included in the semiconductor device according to the embodiment.

FIG. 7 is a sectional view showing an example of a method of manufacturing the semiconductor device according to the embodiment.

FIG. 8 is a sectional view showing an example of the method of manufacturing the semiconductor device according to the embodiment.

FIG. 9 is a sectional view showing an example of the method of manufacturing the semiconductor device according to the embodiment.

FIG. 10 is a sectional view illustrating an example of a structure of a gate insulating film of a transistor included in a semiconductor device according to a first modification.

FIG. 11 is a sectional view showing an example of a method of manufacturing the semiconductor device according to the first modification.

FIG. 12 is a sectional view showing an example of the method of manufacturing the semiconductor device according to the first modification.

FIG. 13 is a sectional view showing an example of a method of manufacturing a semiconductor device according to a second modification.

FIG. 14 is a sectional view illustrating an example of a structure of a gate insulating film of a transistor included in a semiconductor device according to another example of the second modification.

FIG. 15 is a sectional view illustrating an example of a structure of a gate insulating film of a transistor included in a semiconductor device according to a further example of the embodiment.

FIG. 16 is a sectional view showing an example of a method of manufacturing a semiconductor device according to the further example of the embodiment.

### DETAILED DESCRIPTION

In general, according to one embodiment, a semiconductor device includes: a first electrode; a second electrode which is in contact with an upper surface of the first electrode; a third electrode provided above the second electrode; an oxide semiconductor which is in contact with an upper surface of the second electrode and which extends in a first direction from the second electrode toward the third electrode; a first conductor provided next to the oxide semiconductor; and a first insulating film provided between the first conductor and the oxide semiconductor, wherein: the first insulating film includes a first region and a second region, the second region being sandwiched between the first region and the oxide semiconductor in a second direction intersecting the first direction; and a first concentration of nitrogen in the first region is higher than a second concentration of nitrogen in the second region.

Embodiments will be described below with reference to the drawings. The dimensions or ratios in the drawings are not necessarily the same as the actual ones. In the following description, components having substantially the same or similar function and configuration are denoted by the same reference symbol. To particularly distinguish the components, different letters or numerals may be added to the ends of the same reference symbols.

In the following description, the wording “two different elements are connected” means that they are electrically connected. The wording also implies that they are electrically connected via a different element. In addition, the wording “elements are electrically connected” may include a form where elements are connected via an insulator as long as the elements can operate in the same manner as the electrically connected elements.

### 1 EMBODIMENT

A semiconductor device according to an embodiment will be described below.

### 1.1 Configuration

A configuration of the semiconductor device according to the embodiment will be described.

### 1.1.1 Memory System

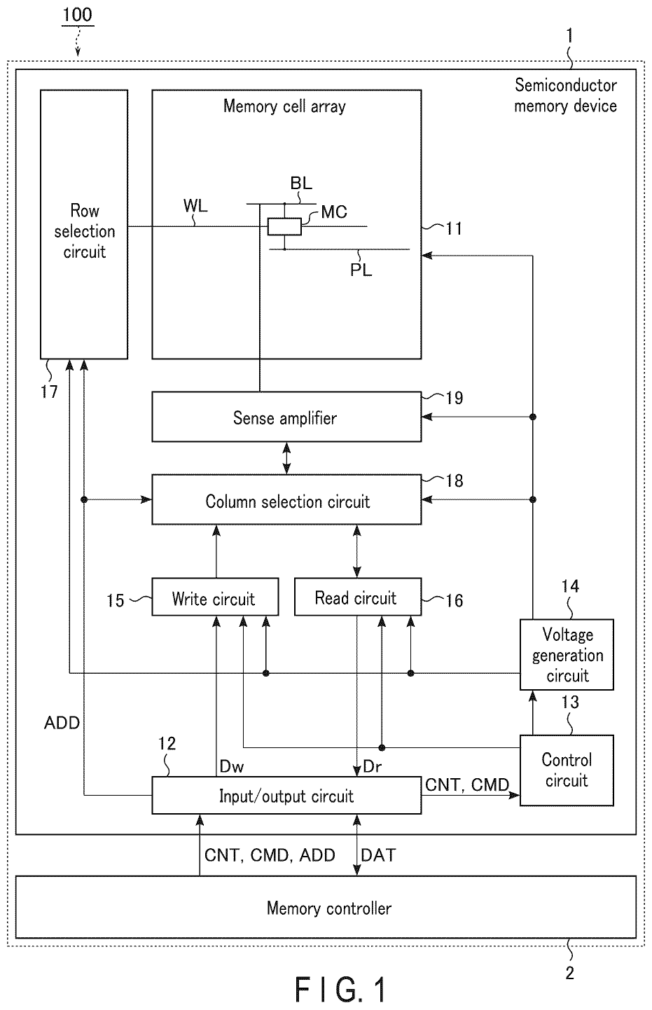

A configuration of a memory system including the semiconductor device according to the embodiment will be described with reference to FIG. 1. FIG. 1 is a block diagram showing an example of the configuration of the memory system including the semiconductor device according to an embodiment.

The memory system 100 performs a data write operation, a data read operation and the like in response to an instruction from a non-illustrated host device external to the memory system 100.

The memory system 100 includes a semiconductor device 1 and a memory controller 2.

The semiconductor device 1 is a storage device using a transistor to select a storage element. The semiconductor device 1 stores data using a capacitor, for example. The semiconductor device 1 is, for example, a dynamic random access memory (DRAM). The memory controller 2 controls the semiconductor device 1.

The semiconductor device 1 includes a memory cell array 11, an input/output circuit 12, a control circuit 13, a voltage generation circuit 14, a write circuit 15, a read circuit 16, a row selection circuit 17, a column selection circuit 18 and a sense amplifier 19.

The memory cell array 11 includes a plurality of memory cells MC, a plurality of word lines WL, a plurality of bit lines BL and a plate line PL. In FIG. 1, one memory cell MC, one word line WL and one bit line BL are illustrated. Each of the memory cells MC stores one-bit data. Each of the memory cells MC is connected between one of the bit lines BL and the plate line PL. In addition, each of the memory cells MC is connected to one of the word lines WL. The word lines WL are associated with rows. The bit lines BL are associated with columns. In the memory cell array 11, one memory cell MC is specified by selecting one row and by selecting one column.

The input/output circuit 12 receives a control signal CNT, a command CMD, an address signal ADD and data DAT from the memory controller 2. The input/output circuit 12 transmits the data DAT to the memory controller 2. The data DAT serves as write data in instances where it is written to the semiconductor device 1. The data DAT serves as read data in instances where it is read from the semiconductor device 1.

The control circuit 13 receives the control signal CNT and the command CMD from the input/output circuit 12. In response to the control signal CNT and command CMD, the control circuit 13 instructs the write circuit 15 to write data to the semiconductor device 1. In response to the control signal CNT and command CMD, the control circuit 13 instructs the read circuit 16 to read data from the semiconductor device 1. In response to the control signal CNT and command CMD, the control circuit 13 instructs the voltage generation circuit 14 to generate a voltage.

According to an instruction from the control circuit 13, the voltage generation circuit 14 generates various voltages. The voltage generation circuit 14 applies the generated voltages to the memory cell array 11, write circuit 15, read circuit 16, row selection circuit 17, column selection circuit 18 and sense amplifier 19.

The write circuit 15 performs processing and control for writing data to the memory cells MC. The write circuit 15 receives write data Dw from the input/output circuit 12. The write data Dw is data to be written to a target memory cell MC. The write circuit 15 receives one or more voltages from the voltage generation circuit 14 for use in a data write operation. Based on the control of the control circuit 13 and the write data Dw, the write circuit 15 supplies one or more voltages to the column selection circuit 18 for use in a data write operation.

The read circuit 16 performs processing and control for reading data from the memory cells MC. The read circuit 16 receives from the voltage generation circuit 14 one or more voltages to be used in a data read operation. Under the control of the control circuit 13, the read circuit 16 determines the data stored in the memory cells MC using the voltages used for the data read operation. The determined data is supplied to the input/output circuit 12 as read data Dr.

The row selection circuit 17 receives the address signal ADD from the input/output circuit 12. The row selection circuit 17 supplies a voltage from the voltage generation circuit 14 to the memory cell array 11. Thus, the row selection circuit 17 places one word line WL that is associated with a row specified by the received address signal ADD in a selected state.

The column selection circuit 18 receives the address signal ADD from the input/output circuit 12. The column selection circuit 18 supplies a voltage from the voltage generation circuit 14 to the memory cell array 11. Thus, the column selection circuit 18 places a bit line BL that is associated with a column specified by the received address signal ADD in a selected state.

The sense amplifier 19 uses the voltage received from the voltage generation circuit 14 to amplify the voltage of the bit line BL in order to determine the data stored in a memory cell MC, for the data read operation.

### 1.1.2 Circuit Configuration of Memory Cell Array

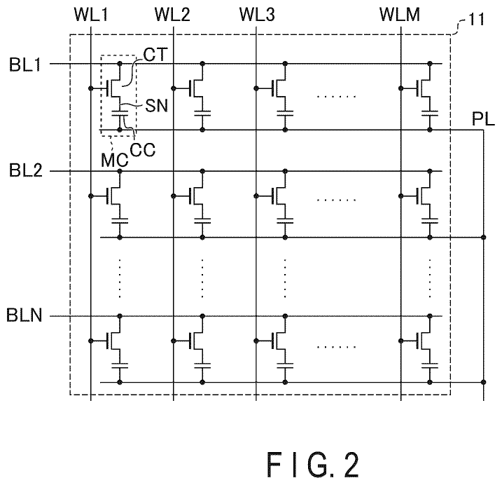

The circuit configuration of a memory cell array included in the semiconductor device according to the embodiment will be described with reference to FIG. 2. FIG. 2 is a circuit diagram showing an example of the circuit configuration of the memory cell array included in the semiconductor device according to the embodiment.

The memory cell array MCA includes M word lines WL (WL1 to WLM), N bit lines BL (BL1 to BLN), and a plate line PL. M and N are positive integers.

Each bit line BL is coupled to, for example, M memory cells MC of the plurality of memory cells MC, which correspond to the bit line BL. The M memory cells MC correspond to, for example, M word lines WL.

Each memory cell MC includes a cell capacitor CC and a cell transistor CT.

The cell transistor CT is, for example, an n-type metal oxide semiconductor field effect transistor (MOSFET). Hereinafter, one of the source and drain of the cell transistor CT will simply be referred to as one end of the cell transistor CT, and the other will simply be referred to as the other end of the cell transistor CT. One end of each cell transistor CT is coupled to one bit line BL corresponding to the cell transistor CT. The gate of each cell transistor CT is coupled to one word line WL corresponding to the cell transistor CT.

A semiconductor that is part of the cell transistor CT includes a region (channel region) in which a channel is formed. The material of the semiconductor includes an oxide semiconductor. The material of the semiconductor may be, for example, constituted by an oxide semiconductor. Note that if the material is constituted by an element A, it may include unintended impurities different from the element A.

The cell capacitors CC are capacitive elements. An electrode at one end of each cell capacitor CC is coupled to the other end of a cell transistor CT corresponding to the cell capacitor CC. An electrode at the other end of the cell capacitor CC is coupled to the plate line PL. The cell capacitor CC stores data based on charges accumulated in the node coupled to the cell transistor CT. Hereinafter, the node will also be referred to as a storage node SN.

The amount of charges accumulated in the storage node SN specifies a state in which the memory cell MC stores “1” data or a state in which the memory cell MC stores “0” data. Hereinafter, as an example, a state in which the potential of the storage node SN is charged to a potential that is relatively equal to or higher than the potential of the plate line PL is assumed to be a state in which the memory cell MC stores “1” data. In addition, a state in which the potential of the storage node SN is charged to a potential that is relatively lower than the potential of the plate line PL is assumed to be a state in which the memory cell MC stores “0” data.

With the above-described configuration, in each memory cell MC, the cell capacitor CC and the cell transistor CT are coupled in series between the bit line BL corresponding to the memory cell MC and the plate line PL.

### 1.1.3 Planar Layout of Memory Cell Array

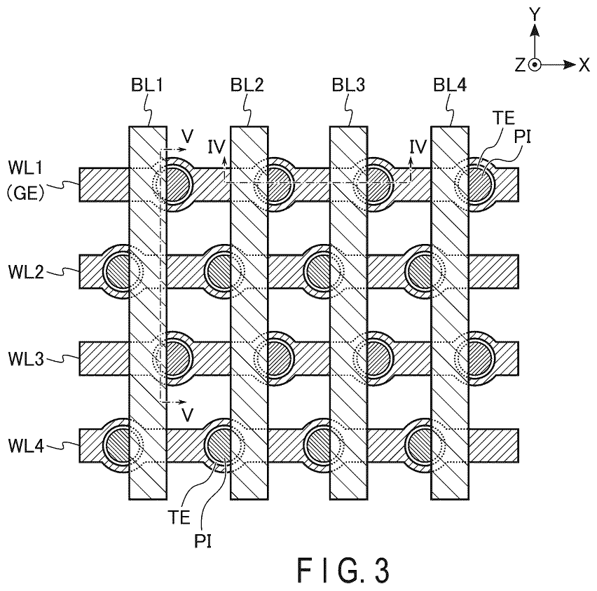

A planar layout of the memory cell array 11 included in the semiconductor device 1 according to the embodiment will be described with reference to FIG. 3. FIG. 3 is a plan view showing an example of the planar layout of the memory cell array included in the semiconductor device 1 according to the embodiment. In FIG. 3, as the example, four word lines WL1 to WL4 and four bit lines BL1 to BL4 are shown.

In the following description, the X direction is substantially parallel to the substrate of the semiconductor device 1. The X direction corresponds to the extending direction of the word lines WL. The Y direction is substantially parallel to the substrate of the semiconductor device 1 and orthogonal to the X direction. The Y direction corresponds to the extending direction of the bit lines BL. The Z direction is substantially perpendicular to the substrate. In the Z direction, the side toward the memory cell array 11 from the substrate is referred to as an upper side. In the Z direction, the side toward the substrate from the memory cell array 11 is referred to as a lower side. Among two surfaces of a component which are orthogonal to the Z direction, the surface on the upper side is referred to as an upper surface and the surface on the lower side is referred to as a lower surface.

The memory cell array 11 includes a plurality of pillars PI and a plurality of upper electrodes TE associated with the bit lines BL and word lines WL. Each pillar PI functions as, for example, one vertical transistor. Each pillar PI corresponds to the cell transistor CT. In the embodiment, each of a plurality of gate electrodes GE functions as a word line WL.

In FIG. 3, four rows of pillar PI groups are shown. The four rows of pillar PI groups are provided to correspond to their respective word lines WL1 to WL4. In each row, four pillars PI are arranged along the X direction. The arrangements of four pillars PI in each of the two adjacent rows of pillar PI groups are, for example, similar. The locations of four pillars PI in one of the adjacent rows and those of four pillars PI in the other row are different in the X direction. In other words, four pillars PI in one of the adjacent rows and those in the other row are displaced in the X direction. Note that in the example of FIG. 3, each of the four rows of pillar PI groups includes four pillars PI, but the number of rows of pillars PI is not limited to four, nor is the number of pillars PI in each of the rows. The number of rows of pillars PI and the number of pillars PI in each of the rows may be changed appropriately.

Each pillar PI and its corresponding bit line BL are coupled together via the upper electrode TE. The bit lines BL extend along the Y direction and are arranged along the X direction. Hereinafter, of the bit lines BL1 and BL4, the side of the bit line BL1 will be referred to as a one-end side in the X direction, and the side of the bit line BL4 will be referred to as the other-end side in the X direction. Each of the bit lines BL is provided to overlap at least part of one of the pillars PI in each row when viewed in the Z direction. Each bit line BL overlaps, for example, the one-end side portion of the pillar PI included in the row corresponding to the word line WL1 or WL3 (included in the odd-numbered row) in the X direction. The bit line BL also overlaps, for example, the other-end side portion of the pillar PI included in the row corresponding to the word line WL2 or WL4 (included in the even-numbered row) in the X direction.

Each bit line BL is electrically connected to the pillars PI overlapping the bit line BL. The number of pillars PI overlapping each bit line BL may be set discretionarily in accordance with the number of word lines WL.

The gate electrodes GE (word lines WL) each extend in the X direction as described above and are arranged in the Y direction. Each of the gate electrodes GE is provided to surround its corresponding pillars PI when viewed in the Z direction.

### 1.1.4 Sectional Structure of Memory Cell Array

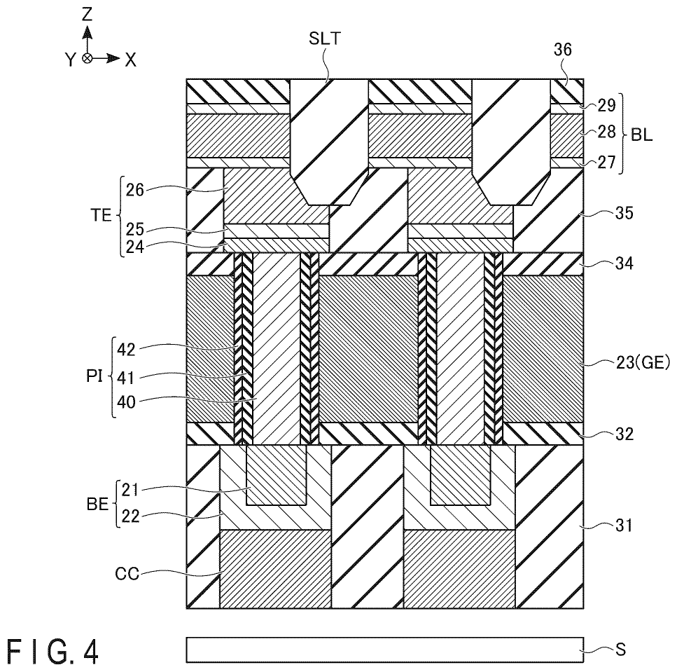

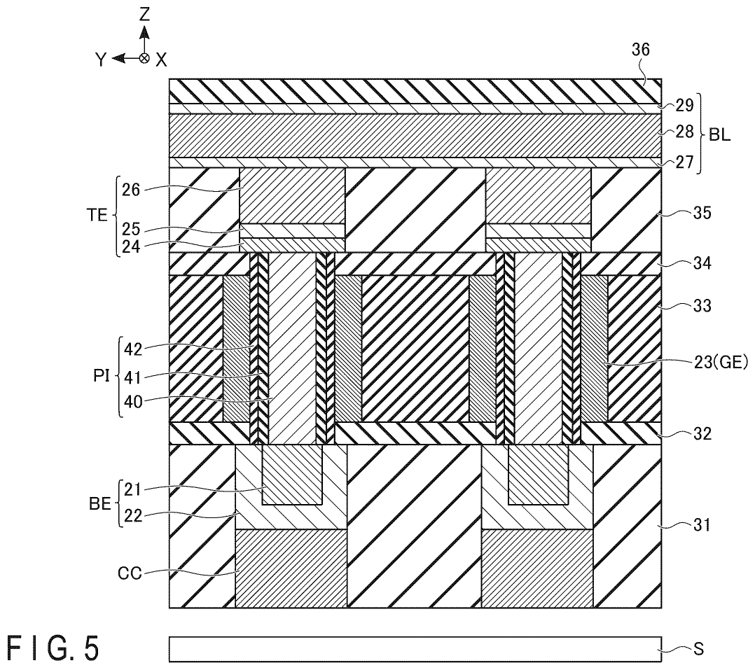

The sectional structure of the memory cell array 11 included in the semiconductor device 1 according to the embodiment will be described with reference to FIGS. 4 and 5. FIG. 4 is a sectional view taken along line IV-IV of FIG. 3 and showing an example of a sectional structure of the memory cell array included in the semiconductor device according to the embodiment. FIG. 5 is a sectional view taken along line V-V of FIG. 3 and showing an example of the sectional structure of the memory cell array included in the semiconductor device according to the embodiment.

The memory cell array 11 includes a plurality of conductors 21 to 29, a plurality of insulators 31 to 36, a plurality of oxide semiconductors 40, a plurality of gate insulating films 41 and 42, and members SLT.

The insulator 31 is provided above the substrate S.

In the same layer level as the insulator 31, an electrode at one end of each of the cell capacitors CC is included. Hereinafter, such an electrode at one end of the capacitor CC will also be simply referred to as the cell capacitor CC. The cell capacitors CC contain a material having conductivity. The material includes silicon (Si), for example. The material is, for example, silicon germanium. The cell capacitors CC have, for example, the shape of a column extending along the Z direction. Note that the XY section of the column may be, for example, circular or rectangular, and is not particularly limited.

In the same layer level as the insulator 31, a plurality of conductors 21 are provided above their corresponding cell capacitors CC. The conductors 21 contain a conductive oxide, for example. The conductors 21 include, for example, oxygen (O) and at least one metallic element selected from the group consisting of indium (In), gallium (Ga), zinc (Zn), magnesium (Mg), aluminum (Al), manganese (Mn), tin (Sn), titanium (Ti), tantalum (Ta), calcium (Ca), tungsten (W) and molybdenum (Mo). The conductors 21 include, for example, indium (In), tin (Sn) and oxygen (O). The conductors 21 include, for example, Indium Tin Oxide (ITO). The lower and side surfaces of each conductor 21 are provided with the conductor 22 corresponding to the conductor 21. The upper surfaces of the conductors 21 and 22 are flush with the upper surface of the insulator 31.

The lower surface of each conductor 22 is in contact with the upper surface of the cell capacitor CC corresponding to the conductor 22. A set of mutually corresponding conductors 21 and 22 functions as a lower electrode BE.

On the upper surfaces of the insulator 31 and conductors 21 and 22, the insulators 32, 33 and 34 are provided upward in the order presented.

The oxide semiconductors 40 are provided to correspond to the conductors 21 and 22. Each oxide semiconductor 40 is provided on the upper surface of the conductor 21 corresponding to the oxide semiconductor 40. Each oxide semiconductor 40 is so provided that its lower surface is in contact with the upper surface of the conductor 21. The oxide semiconductors 40 penetrate the insulators 32 to 34. The oxide semiconductors 40 are made of, for example, oxide semiconductors. The oxide semiconductors 40 include, for example, at least one element of indium (In), gallium (Ga), zinc (Zn), aluminum (Al), or tin (Sn). The oxide semiconductors 40 include, for example, zinc (Zn) and at least one element of indium (In), gallium (Ga), silicon (Si), aluminum (Al), or tin (Sn). The oxide semiconductors 40 include an indium-gallium-zinc oxide, for example.

As described above, the conductor 21 corresponding to a given oxide semiconductor 40 is provided between this oxide semiconductor 40 and the conductor 22 corresponding to the oxide semiconductor 40. In this structure, the conductor 21 is provided to reduce the contact resistance between the conductor 22 and the oxide semiconductor 40.

The gate insulating films 41 and 42 are provided on the side surfaces of each oxide semiconductor 40.

The gate insulating film 41 is provided on at least part of the side surface of the oxide semiconductor 40. The gate insulating film 41 includes an insulator. The gate insulating film 41 includes, for example, silicon oxide, silicon oxynitride, metal oxide, or metal oxynitride. The metal included in the metal oxide and the metal oxynitride is, for example, at least one element of aluminum (Al), hafnium (Hf) or zirconium (Zr). A more detailed structure of the gate insulating film 41 will be described later.

The gate insulating film 42 is provided to cover the side surface of the gate insulating film 41. The gate insulating film 42 includes an insulator. The gate insulating film 42 includes, for example, silicon nitride, metal oxide, metal nitride, or metal oxynitride. The metal included in the metal oxide, metal nitride and metal oxynitride is, for example, at least one element of aluminum (Al), hafnium (Hf) or zirconium (Zr). Note that the gate insulating film 42 is a monolayer film including a single layer containing silicon nitride, metal oxide, metal nitride or metal oxynitride, or a stacked film including a plurality of layers each containing silicon nitride, metal oxide, metal nitride or metal oxynitride. The embodiment assumes inclusion of the gate insulating film 42, but the gate insulating film 42 may be omitted.

The thickness of each of the gate insulating films 41 and 42 along the X or Y direction is, for example, 7 nanometers (nm) or less.

A set of an oxide semiconductor 40 and gate insulating films 41 and 42 corresponding to each other functions as a pillar PI. Each oxide semiconductor 40 corresponds to a semiconductor constituting part of the cell transistor CT. The upper surfaces of the oxide semiconductors 40 and those of the gate insulating films 41 and 42 are flush with the upper surface of the insulator 34.

Note that the pillar PI may have a tapered shape. The pillar PI may also have a bowed shape in which the central part along the Z direction is inflated.

A plurality of conductors 23 are provided in the same layer level as the insulator 33. Each of the conductors 23 functions as the gate electrode GE (word line WL). The conductors 23 correspond to the respective gate electrodes GE and extend in the X direction. Thus, in the XZ section shown in FIG. 4, the conductors 23 are in contact with the side surfaces of the pillars PI arranged in the X direction. In addition, the conductors 23 are arranged in the Y direction to correspond to the gate electrodes GE. Thus, in the YZ section shown in FIG. 5, each conductor 23 is in contact with the side surface of one pillar PI corresponding to the conductor 23. In addition, each conductor 23 is provided next to the oxide semiconductor 40 corresponding to the conductor 23. Also, the gate insulating film 41 corresponding to the oxide semiconductor 40 is provided between the conductor 23 and the oxide semiconductor 40.

An insulator 35 is provided on the upper surface of the insulator 34, the upper surfaces of the oxide semiconductors 40 and the upper surfaces of the gate insulating films 41 and 42.

A plurality of conductors 24 are provided in the same layer level as the insulator 35 to correspond to the pillars PI. Each conductor 24 is provided on an upper surface of the oxide semiconductor 40 of the pillar PI corresponding to the conductor 24. Each conductor 24 is provided to cover the upper surface of the oxide semiconductor 40 corresponding to the conductor 24. The conductors 24 include a conductive oxide, for example. The conductors 24 include, for example, oxygen (O) and at least one metallic element selected from the group consisting of indium (In), gallium (Ga), zinc (Zn), magnesium (Mg), aluminum (Al), manganese (Mn), tin (Sn), titanium (Ti), tantalum (Ta), calcium (Ca), tungsten (W) and molybdenum (Mo). The conductors 24 include, for example, an oxide of at least one element of indium (In) or tin (Sn). This conductive oxide includes at least one compound of indium tin oxide or tin oxide.

A plurality of conductors 25 are provided on the upper surfaces of the conductors 24 to correspond to the conductors 24. The conductors 25 include, for example, at least one element of titanium (Ti), tin (Sn), zinc (Zn), ruthenium (Ru), or niobium (Nb). The conductors 25 also include, for example, a nitride of at least one of these elements. The conductors 25 include, for example, titanium nitride (TiN).

A plurality of conductors 26 are provided on the upper surfaces of the conductors 25 to correspond to the conductors 25. The conductors 26 include, for example, tungsten (W). The upper surfaces of the conductors 26 are flush with the upper surface of the insulator 35. In the Z direction, the thickness of each of the conductors 26 is, for example, greater than that of each of the conductors 24 and 25.

In the foregoing structure, a set of conductors 24 to 26 corresponding to each other functions as the upper electrode TE. Each conductor 25 is provided to prevent metallic elements contained in the conductor 26 corresponding to the conductor 25 from penetrating into the conductor 24 by diffusion. It may therefore be said that the conductors 25 can function as, for example, a barrier metal.

A plurality of conductors 27 are provided on the upper surface of the insulator 35 and on the upper surfaces of the conductors 26 to correspond to the upper electrodes TE. Each conductor 27 is provided in contact with the conductors 26 of the upper electrodes TE corresponding to the conductor 27. Each conductor 27 extends along the Y direction to correspond to the bit line BL. The upper electrodes TE corresponding to each conductor 27 correspond to different word lines WL. The conductors 27 are arranged in the X direction to correspond to the bit lines BL. The conductors 27 include, for example, titanium nitride (TiN).

A conductor 28 is provided on the upper surface of each conductor 27 to correspond to the conductor 27. The conductors 28 include, for example, tungsten (W).

A conductor 29 is provided on the upper surface of each conductor 28 to correspond to the conductor 28. The conductors 29 include, for example, titanium nitride (TiN).

In the foregoing structure, the conductors 27, 28 and 29 corresponding to each other function as a bit line BL. The conductors 27 and 29 are provided to prevent metal elements contained in the conductors 28 from diffusing into the layer below the conductors 27 and the layer above the conductors 29. It may therefore be said that the conductors 27 and 29 can function as, for example, a barrier metal. Note that the conductors 27 and 29 may be omitted.

An insulator 36 is provided on the upper surfaces of the conductors 29.

A plurality of members SLT are provided above the insulator 34. The members SLT extend along the Y direction and are arranged along the X direction. Each member SLT is provided to penetrate the conductors 27 to 29. The upper surface of each of the members SLT is flush with that of the insulator 36, for example. The lower surface of each of the members SLT is in contact with, for example, the conductor 26. Note that the lower surface of each member SLT has only to reach the height of the upper surface of the insulator 35. The members SLT are, for example, insulators such as silicon oxide. With the foregoing structure, the two bit lines BL next to each other in the X direction are separated from each other by the member SLT corresponding to these two bit lines BL. The two bit lines BL are insulated from each other by the member SLT.

In the XZ section including the word line WL1 or WL3, each member SLT is provided to overlap, for example, one-end side portion of the upper electrode TE in the X direction. In the XZ section including the word line WL2 or WL4, each member SLT is provided to overlap, for example, the other-end side portion of the upper electrode TE in the X direction. The XZ section shown in FIG. 4 is an example where each member SLT is provided to overlap the other-end side portion of the upper electrode TE corresponding to the member SLT.

### 1.1.5 Structure of Gate Insulating Film

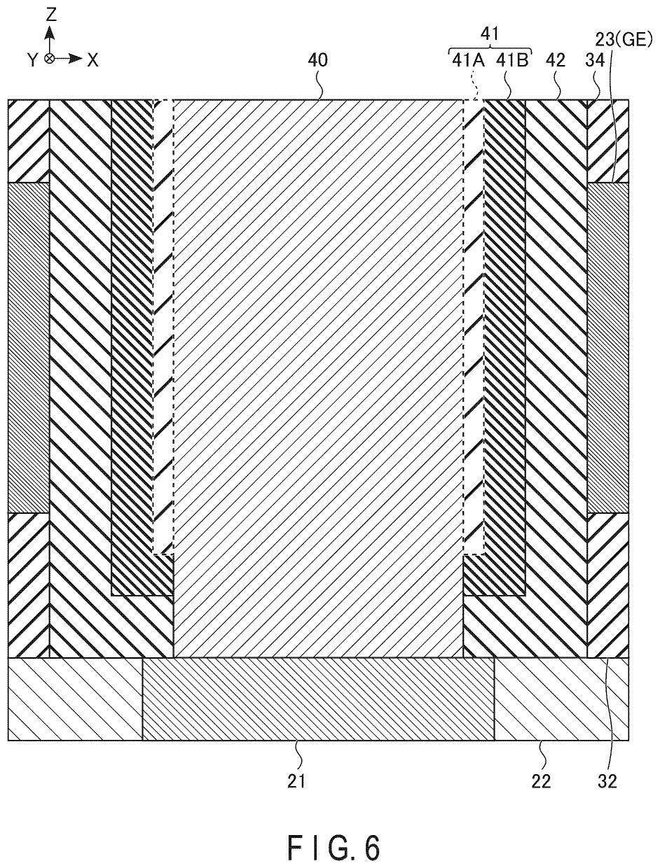

The structure of the gate insulating film 41 will be described below with reference to FIG. 6. FIG. 6 is a sectional view illustrating an example of the structure of a gate insulating film of the transistor included in the semiconductor device according to the embodiment.

The gate insulating film 41 is provided above the conductor 21. The gate insulating film 41 is thus separated from the conductor 21, for example. The gate insulating film 41 covers, for example, the side surface of the oxide semiconductor 40 within a range from a height above the upper surface of the conductor 21 to the height of the upper surface of the oxide semiconductor 40. The gate insulating film 42 covers, for example, the side and bottom surfaces of the gate insulating film 41.

The gate insulating film 41 includes regions 41A and 41B. In FIG. 6, the region 41A is surrounded by dotted lines.

The region 41A is, for example, provided in contact with the side surface of the oxide semiconductor 40. The region 41A covers, for example, the side surface of the oxide semiconductor 40 within a range from a height above the bottom surface of the gate insulating film 41 to the height of the top surface of the oxide semiconductor 40. Note that the region 41A may be provided entirely from the height of the top surface to the height of the bottom surface of the gate insulating film 41.

The region 41B is, for example, the gate insulating film 41 excluding the region 41A. The region 41A is sandwiched between the region 41B and the oxide semiconductor 40 in the X and Y directions. In addition, the region 41B is provided in contact with, for example, a portion of the side surface of the oxide semiconductor 40 which is located under the region 41A and on which the region 41A is not provided. For example, the conductor 21 is in contact with the oxide semiconductor 40, not the gate insulating film 41.

The region 41A is formed by, for example, a nitriding process to be described later. In the gate insulating film 41, the region 41A has a higher concentration of nitrogen (N) atoms than the region 41B. The concentration of nitrogen (N) atoms in the region 41A is, for example, 1×1015 atoms/cm3 or higher and 1×1018 atoms/cm3 or lower. The gate insulating film 41 may have a concentration gradient such that in the XY section including the regions 41A and 41B, the concentration of nitrogen (N) atoms gradually decreases from the region 41A side toward the region 41B side (from the oxide semiconductor 40 toward the conductor 23). In addition, for example, if the region 41B has a portion under the region 41A as described above, the gate insulating film 41 includes a region 41B whose nitrogen (N) concentration is lower than that of the region 41A between the region 41A and each of the gate insulating film 42 and conductor 21 along the Z direction.

If the gate insulating film 41 includes silicon oxide or silicon oxynitride, the gate insulating film 41 includes, for example, silicon oxynitride in the region 41A. In this case, in the region 41B, the gate insulating film 41 includes silicon oxide or silicon oxynitride. If the gate insulating film 41 includes metal oxide or metal oxynitride, the gate insulating film 41 includes, for example, metal oxynitride in region 41A. In this case, in the region 41B, the gate insulating film 41 includes metal oxide or metal oxynitride.

Furthermore, for example, the concentration of nitrogen (N) atoms in the gate insulating film 42 is higher than that in the region 41A. In this case, the conductor 23 can be prevented from being oxidized. Note that the concentration of nitrogen (N) atoms in the gate insulating film 42 may be lower than that in the region 41A depending upon the material of the conductor 23.

### 1.2 Manufacturing Method

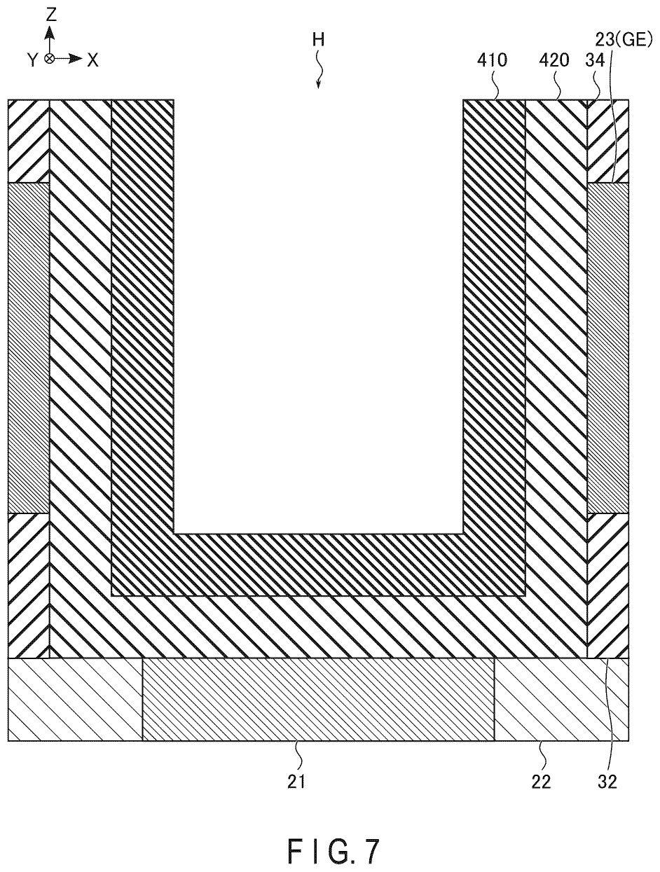

A method of manufacturing the semiconductor device 1 according to the embodiment will be described below with reference to FIGS. 7, 8 and 9. FIGS. 7, 8 and 9 are sectional views showing an example of a method of manufacturing the semiconductor device according to the embodiment. The sections shown in FIGS. 7 to 9 correspond to the section shown in FIG. 6.

First, an insulator 31, a plurality of cell capacitors CC and a plurality of lower electrodes BE are provided above the substrate S.

Then, insulators 32, 33 and 34 and a plurality of conductors 23 are formed. In addition, a plurality of holes H corresponding to a plurality of pillars PI are formed. The holes H are formed to extend from the upper surface of the insulator 34 to the upper surfaces of the conductors 21 and 22 by photolithography, anisotropic etching and the like. The anisotropic etching is reactive ion etching (RIE), for example.

Then, as shown in FIG. 7, insulators 420 and 410 are formed sequentially in this order, for example, so as to cover the side and bottom surfaces in the hole H. The insulators 410 and 420 correspond to the gate insulating films 41 and 42, respectively. The material of the insulator 410 is equivalent to, for example, the composition of the gate insulating film 41 in the region 41B. The material of the insulator 420 is equivalent to, for example, the composition of the gate insulating film 42.

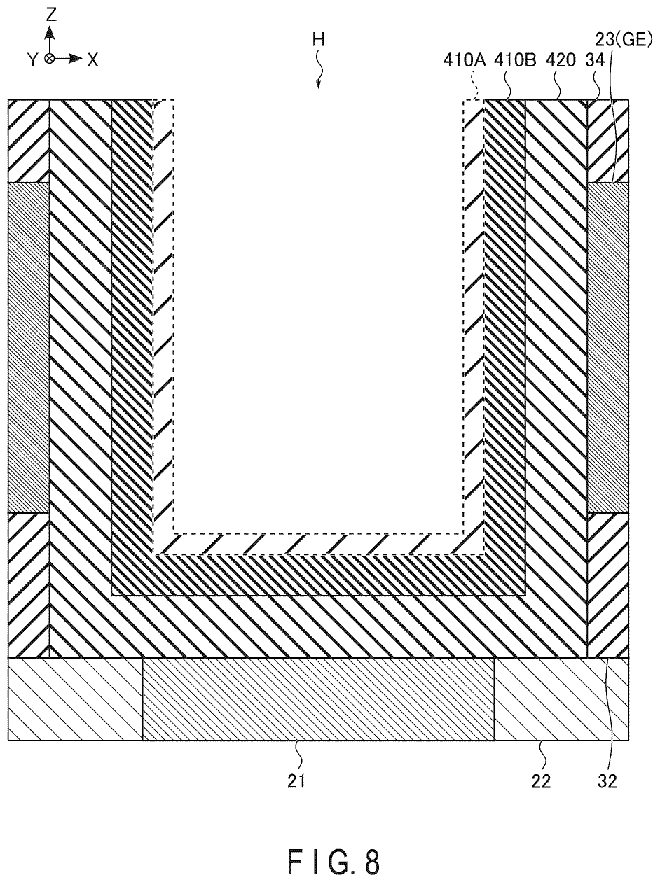

Then, a process of nitriding the inner surfaces of the hole H, where the insulator 410 is formed, is performed. This surface nitriding process is a plasma isotropic nitriding process, for example. By this process, the insulator 410 is divided into a nitrided region 410A and a non-nitrided region 410B, as shown in FIG. 8. For example, in FIG. 7, a region of the insulator 410, which is exposed inside the hole H, is turned into the region 410A. The region 410A is formed apart from the insulator 420 and conductor 21. The material of the insulator 410 in the region 410A is made equivalent to the composition of the gate insulating film 41 in the region 41A by the surface nitriding process. In addition, for example, the insulator 410 excluding the region 410A serves as the region 410B.

The material of the insulator 410 in the region 410B is kept equal to the composition of the gate insulating film 41 in the region 41B. The region 410B is interposed between the insulator 420 and the region 410A.

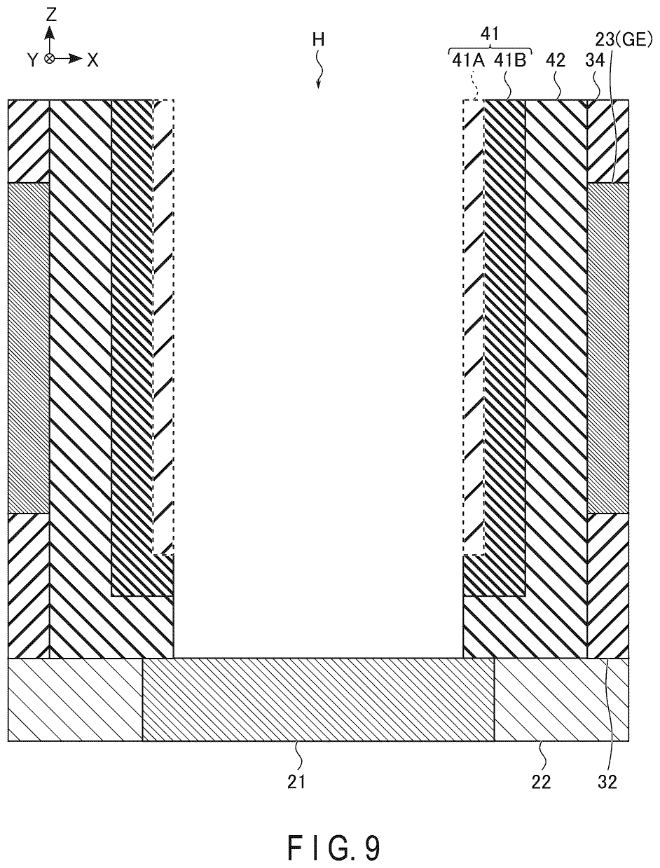

As shown in FIG. 9, the gate insulating film 41 including the regions 41A and 41B and the gate insulating film 42 are formed by removing the bottom portion of the hole H. More specifically, a portion of the insulator 410 and a portion of the insulator 420, which constitute the bottom portion of the hole H in FIG. 8, are removed by anisotropic etching using a mask, for example. The anisotropic etching is, for example, RIE. This step is continued until the upper surface of the conductor 21 is exposed. Upon removal of the portions of the insulators 410 and 420 by this step, a region included in the region 410A serves as the region 41A of the gate insulating film 41. Also, a region included in the region 410B serves as the region 41B of the gate insulating film 41. The insulator 420 serves as the gate insulating film 42.

Then, a plurality of oxide semiconductors 40 are embedded in their respective holes H. In addition, a plurality of conductors 24 to 29, a plurality of insulators 35 to 36, and a member SLT are formed.

The semiconductor device 1 is therefore manufactured by the above process.

### 1.3 Effects

According to the embodiment, the semiconductor device can be improved in its reliability. The effects of the semiconductor device according to the embodiment will be described below.

According to the embodiment, the semiconductor device 1 includes a cell capacitor CC, a lower electrode BE, an upper electrode TE, a pillar PI and a word line WL. The lower electrode BE is in contact with the upper surface of the cell capacitor CC. The upper electrode TE is provided above the lower electrode BE. The pillar PI includes an oxide semiconductor 40 extending in the Z direction and a gate insulating film 41 provided on the side surface of the oxide semiconductor 40. The oxide semiconductor 40 is in contact with the upper surface of the lower electrode BE. The word line WL surrounds at least part of the gate insulating film 41. The gate insulating film 41 includes a region 41A and a region 41B. The region 41A is sandwiched between the region 41B and the oxide semiconductor 40. The concentration of nitrogen (N) atoms contained in the gate insulating film 41 in the region 41A is higher than that in the gate insulating film 41 in the region 41B. With this structure, where the region 41A is provided, the embodiment can prevent metal elements contained in the oxide semiconductor 40 from diffusing toward the gate insulating film 41. Consequently, a dielectric breakdown can be prevented from occurring in the gate insulating film 41. Therefore, the semiconductor device 1 can be improved in its reliability.

More specifically, if there is no region for preventing metal elements from diffusing toward the gate insulating film from the oxide semiconductor of the cell transistor, metal elements such as indium (In), gallium (Ga), zinc (Zn), aluminum (Al) and tin (Sn) may enter the gate insulating film. In this case, for example, these metal elements that have entered the gate insulating film, and electrical stress may cause defects (trap sites) randomly in the gate insulating film. Furthermore, when such defects increase due to the application of voltages for a long period of time, for example, defects are formed like a string of beads between the oxide semiconductor and the gate electrode, thus causing a dielectric breakdown. This breakdown is also referred to as a time dependent dielectric breakdown (TDDB).

According to an embodiment, the region 41A is provided between the region 41B and the side surface of the oxide semiconductor 40 in the gate insulating film 41. In the gate insulating film 41, the region 41A has a higher concentration of nitrogen (N) atoms than the region 41B. Thus, a portion of the gate insulating film 41 included in the region 41A can prevent metal elements such as indium (In), gallium (Ga), zinc (Zn), aluminum (Al) and tin (Sn) included in the oxide semiconductor 40 from diffusing into the region 41B of the gate insulating film 41. That is, the region 41A functions as a barrier region for preventing the metal elements from entering the region 41B from the oxide semiconductor 40. In the gate insulating film 41, therefore, a dielectric breakdown due to the diffusion of metal elements is prevented.

In the embodiment, the gate insulating film 41 includes a portion of the region 41B which is located under the region 41A. The gate insulating film also includes the region 41B and the gate insulating film 42 which are located under the region 41A. This configuration makes it possible to prevent an on current Ion of the cell transistor CT from decreasing. More specifically, such a configuration of the semiconductor device 1 prevents electrons from being trapped by silicon oxynitride and metal oxynitride immediately above the conductor 21.

Accordingly, a fringe electric field is easily applied to an interface between the oxide semiconductor 40 and the conductor 21. In the embodiment, therefore, the characteristics of the on current Ion of the cell transistor CT are improved.

### 2. FIRST MODIFICATION

In the above-described embodiment, a region in the gate insulating film which has a high concentration of nitrogen (N) atoms is provided apart from the conductor of the lower electrode, but this is not a limitation. In the semiconductor device, the region in the gate insulating film which has a high concentration of nitrogen (N) atoms may be provided in contact with the conductor of the lower electrode. The conductor of the lower electrode which is in contact with the oxide semiconductor may also have a region having a high concentration of nitrogen (N) atoms. Hereinafter, a configuration and a manufacturing method of a semiconductor device 1 according to the first modification will be described by concentrating mainly on differences from those of the semiconductor device according to the embodiment.

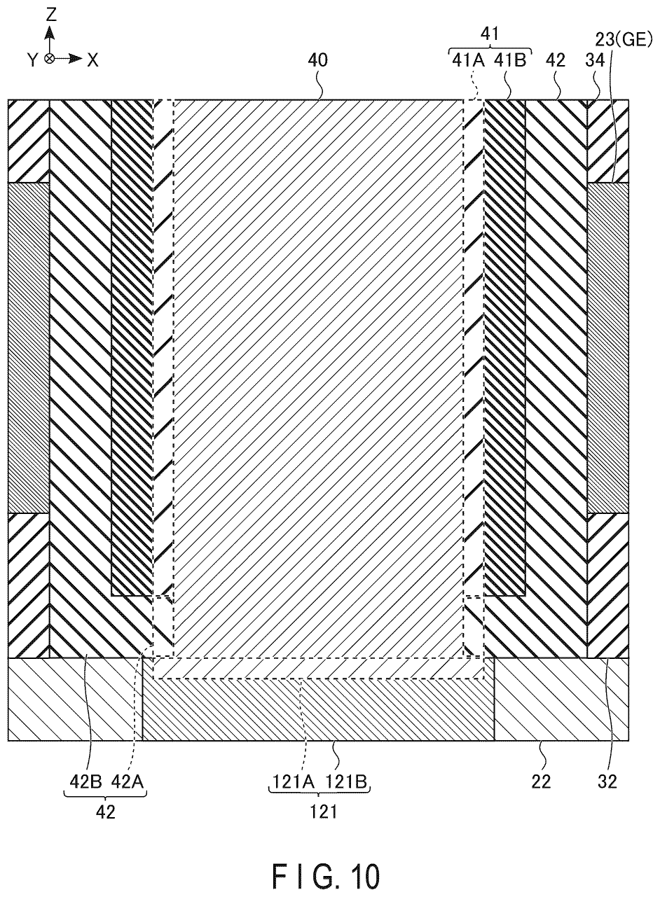

The configuration of the semiconductor device 1 according to the first modification will be described with reference to FIG. 10. FIG. 10 is a sectional view illustrating an example of a configuration of a gate insulating film of a transistor included in the semiconductor device according to the first modification. FIG. 10 corresponds to the section shown in FIG. 6 of the embodiment.

In the first modification, the region 41A of the gate insulating film 41 is provided so as to entirely cover the side surface of the oxide semiconductors 40 which is in the range from the height of the upper surface of the gate insulating film 41 to the height of the lower surface thereof. The region 41B of the gate insulating film 41 is provided so as to cover the entire side surface of the region 41A.

In the first modification, the gate insulating film 42 includes regions 42A and 42B. The region 42A is located under the gate insulating film 41 and in contact with the side surface of the oxide semiconductor 40. The region 42A covers the entire side surface of the oxide semiconductor 40 together with the region 41A. The region 42B corresponds to the gate insulating film 42 excluding the region 42A. In FIG. 10, the region 42A is a region surrounded by dotted lines.

The region 42A is formed by a surface nitriding process, for example, together with the region 41A, as described later. In the gate insulating film 42, for example, the region 42A has a higher concentration of nitrogen (N) atoms than the region 42B. The concentration of nitrogen (N) atoms in the region 42A is, for example, 1×1015 atoms/cm3 or higher and 1×1018 atoms/cm3 or lower. The gate insulating film 42 may be configured to have a concentration gradient such that the concentration of nitrogen (N) atoms gradually lowers from the region 42A side toward the region 42B side (from the oxide semiconductor 40 toward the conductor 23) in the XY section including the regions 42A and 42B.

In the first modification, the lower electrode BE of the semiconductor device 1 includes conductors 121 and 22. That is, the lower electrode BE includes the conductor 121 in place of the conductor 21 of the embodiment. The conductor 121 includes regions 121A and 121B. In FIG. 10, the region 121A is a region surrounded by dotted lines within the conductor 121.

The region 121A is provided in an upper part of the conductor 121. The region 121A is in contact with the lower surfaces of the gate insulating film 42 and the oxide semiconductor 40. Thus, the region 121A, the region 41A of the gate insulating film 41, and the region 42A of the gate insulating film 42 cover the side and lower surfaces of the oxide semiconductor 40. The region 121B corresponds to the conductor 121 excluding the region 121A. The region 121A is sandwiched in the Z direction between the region 121B and the lower surface of the oxide semiconductor 40, and between the region 121B and the portion included in the region 42A of the gate insulating film 42. Although not shown, the region 121A may be provided inside the gate insulating film 42 corresponding to the region 121A when viewed from above. In this case, the region 121A is not in contact with the region 42A.

The region 121A is formed by the surface nitriding process, together with the regions 41A and 42A, for example, as described later. In the conductor 121, the region 121A has a higher concentration of nitrogen (N) atoms than the region 121B. The concentration of nitrogen (N) atoms in the region 121A is, for example, 1×1015 atoms/cm3 or higher and 1×1018 atoms/cm3 or lower. Note that the concentration of nitrogen (N) atoms of the surface of the conductor 22 may be higher than that of a portion of the conductor 22 which is located apart from the gate insulating films 41 and 42.

The conductor 121 contains a conductive oxide that is equivalent to the conductor 21 of the embodiment. The region 121A of the conductor 121 contains a nitride of the conductive oxide (for example, conductive oxynitride). The region 121B of the conductor 121 contains a material that is equivalent to the conductive oxide.

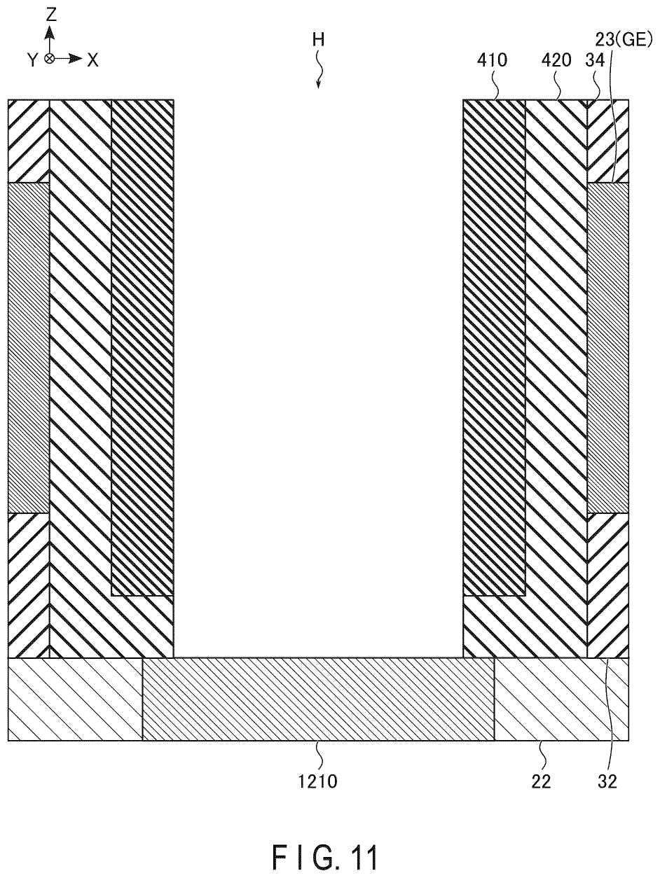

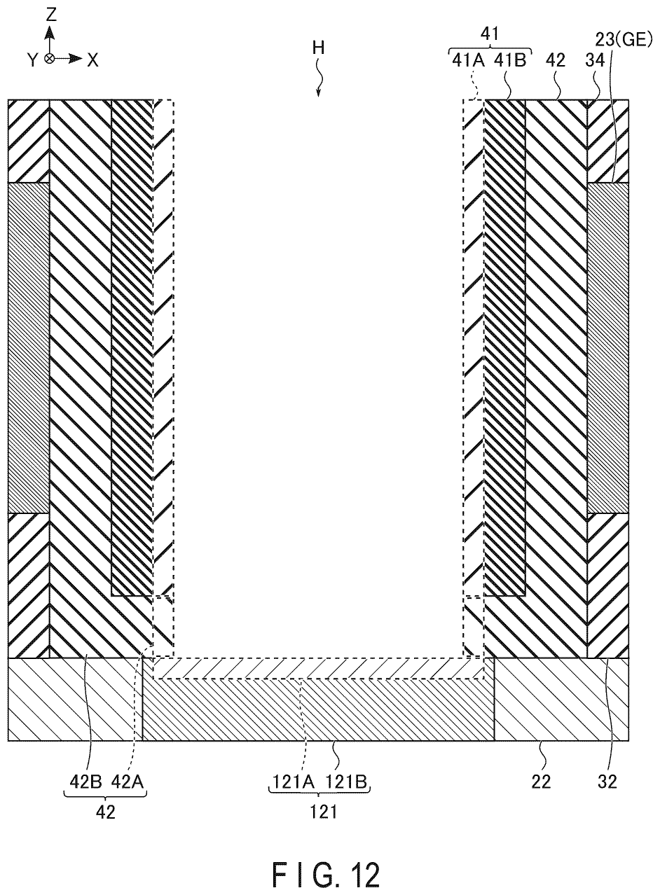

A method of manufacturing the semiconductor device 1 according to the first modification will be described with reference to FIGS. 11 and 12. FIGS. 11 and 12 are sectional views showing an example of a method of manufacturing a semiconductor device according to the first modification. FIGS. 11 and 12 correspond to the section shown in FIG. 10.

In the first modification, insulators 410 and 420 are formed by a step similar to that shown in FIG. 7 of the embodiment. Note that in the first modification, a conductor 1210 is formed instead of the conductor 21 in the embodiment. The material of the conductor 1210 is equivalent to that of the conductor 21 in the embodiment.

The bottom portion of the hole H is removed as shown in FIG. 11 by a process similar to that described with reference to FIG. 9 in the embodiment. Thus, for example, the upper surface of the conductor 1210 is exposed to the interior of the hole H.

Then, a surface nitriding process, which is similar to that described with reference to FIG. 8 of the embodiment, is performed in the hole H where the upper surface of the conductor 1210 is exposed. By this process, as shown in FIG. 12, the insulator 410 is turned into the gate insulating film 41 including the regions 41A and 41B, the insulator 420 is turned into the gate insulating film 42 including the regions 42A and 42B, and the conductor 1210 is turned into the conductor 121 including the regions 121A and 121B. More specifically, for example, in FIG. 11, the region of the insulator 410 that is exposed to the interior of the hole H is turned into the region 41A. For example, the insulator 410 excluding the region 41A serves as the region 41B. For example, in FIG. 11, the region of the insulator 420 that is exposed to the interior of the hole H is turned into the region 42A. For example, the insulator 420 excluding the region 42A serves as the region 42B. For example, in FIG. 11, the region of the conductor 1210 that is exposed to the interior of the hole H is turned into the region 121A of the conductor 121. In addition, for example, the conductor 1210 excluding the region 121A serves as the region 121B of the conductor 121.

Then, a plurality of conductors 24 to 29, insulators 35 to 36, a plurality of oxide semiconductors 40, and a member SLT are formed by a process similar to that in the embodiment.

The semiconductor device 1 according to the first modification is manufactured by the process described above.

The first modification can also improve the reliability of the semiconductor device 1 in a similar manner to the embodiment.

Furthermore, the first modification can reduce the contact resistance between the oxide semiconductor 40 and the conductor 121. As described above, the conductor 121 of the semiconductor device 1 according to the first modification is in contact with the oxide semiconductor 40 and includes the region 121A having a high concentration of nitrogen (N) atoms. Therefore, if the oxide semiconductor 40 contains indium (In), the region 121A of the conductor 121 contains more nitrogen (N) atoms, which have more valence electrons than indium (In), than the region 121B. The first modification can thus decrease the interface resistance between the oxide semiconductor 40 and the conductor 121.

### 3. SECOND MODIFICATION

In the foregoing embodiment and first modification, the inner surfaces of the hole are subjected to nitriding in the manufacturing process so that the gate insulating film or both the gate insulating film and lower electrode include a region having a high concentration of nitrogen atoms, but this is not a limitation. The region having a high concentration of nitrogen atoms may be formed in the gate insulating film or the gate insulating film and lower electrode by a film forming process.

The configuration of a semiconductor device 1 according to a second modification is similar to that of the semiconductor device according to the embodiment, except that a portion of the gate insulating film 41 included in the region 41A is formed by a process of forming a film containing nitrogen (N) atoms. Below is a description of points of difference between the manufacturing method of the semiconductor device 1 according to the second modification and that of the semiconductor device according to the embodiment.

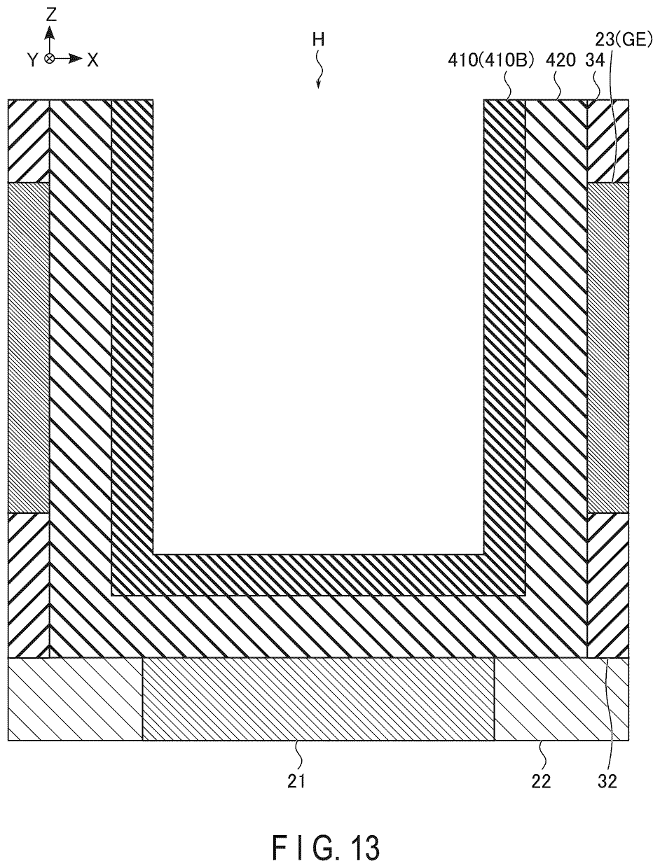

A method of manufacturing the semiconductor device 1 according to the second modification will be described with reference to FIG. 13. FIG. 13 is a sectional view showing an example of the method of manufacturing the semiconductor device according to the second modification.

In the second modification, as shown in FIG. 13, insulators 410 and 420 are formed by a step similar to that shown in FIG. 7 of the embodiment. The insulator 410 formed in this step corresponds to a portion of the region 410B in the embodiment.

A film is formed on the surfaces of the insulator 410 in the hole H by materials containing a silicon oxynitride or a metal oxynitride. This film has a constitution similar to a portion of the region 410A in the embodiment. In this step, a structure similar to that shown in FIG. 8 of the embodiment is formed.

Then, a plurality of conductors 24 to 29, insulators 35 to 36, a plurality of oxide semiconductors 40, gate insulating films 41 and 42, and a member SLT are formed by a process similar to that of the embodiment.

As in the embodiment, the second modification also makes it possible to prevent the semiconductor device 1 from decreasing in its reliability.

Also, as in the embodiment, the region 41A in the second modification is not in contact with the conductor 21. The region 41B having a lower nitrogen concentration than that of the region 41A is included between the region 41A and the conductor 21. Therefore, as in the embodiment, the second modification makes it possible to prevent the on current Ion of the cell transistor CT from decreasing.

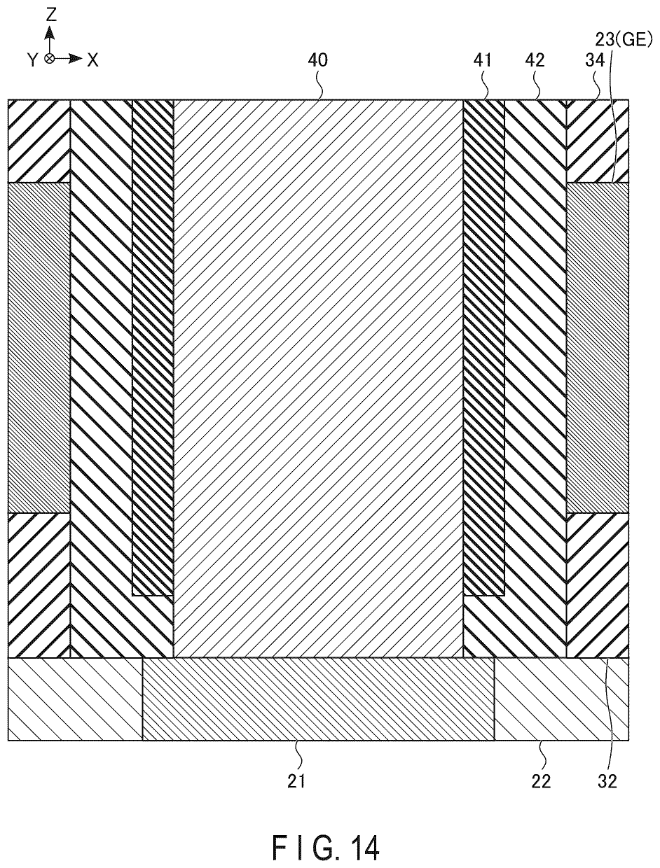

Similar to the embodiment, the second modification has assumed the case where the gate insulating film 41 includes two regions 41A and 41B, but this is not a limitation. In the semiconductor device, as shown in FIG. 14, the entire gate insulating film 41 may be made of materials containing a silicon oxynitride or a metal oxynitride. That is, the gate insulating film 41 may include only one region. FIG. 14 is a sectional view illustrating an example of the structure of a gate insulating film of a transistor included in a semiconductor device according to another example of the second modification.

In the above case, the gate insulating film 41 corresponds to the region having a high concentration of nitrogen atoms. The material of the gate insulating film 41 in this another example of the second modification is equivalent to, for example, that of the region 41A in the embodiment. In this another example of the second modification, the concentration of nitrogen (N) atoms of the gate insulating film 42 is lower than that of the gate insulating film 41. Thus, the gate insulating film 42 corresponds to the region having a low concentration of nitrogen atoms.

In a method of manufacturing the semiconductor device 1 according to another example of the second modification, an insulator 410 corresponding to the gate insulating film 41 having a high concentration of nitrogen atoms is formed, instead of forming the insulator 410 corresponding to the region 410B in FIG. 13. The material of the insulator 410 is equivalent to, for example, that of the gate insulating film 41 in this another example of the second modification. The insulator 410 is formed and then the bottom portion of the hole H is removed so as to form the gate insulating films 41 and 42. As in the embodiment, a plurality of conductors 24 to 29, insulators 35 to 36, a plurality of oxide semiconductors 40, and a member SLT are formed.

The foregoing configuration also makes it possible to prevent the semiconductor device 1 from decreasing in its reliability, as in the embodiment.

In another example of the second modification, the gate insulating film 41 having a high concentration of nitrogen atoms is not in contact with the conductor 21. The gate insulating film 42 having a lower nitrogen concentration than that of the gate insulating film 41 is included between the gate insulating film 41 and the conductor 21. Therefore, as in the embodiment, in another example of the second modification, the on current Ion of the cell transistor CT can be prevented from decreasing.

### 4 OTHERS

In the foregoing embodiment, first modification and second modification, two insulators corresponding to the gate insulating films are formed successively and then the bottom portion of the hole is removed in the manufacturing process, but this is not a limitation. The second insulator may be formed after the bottom portion of the hole of the first insulator is removed.

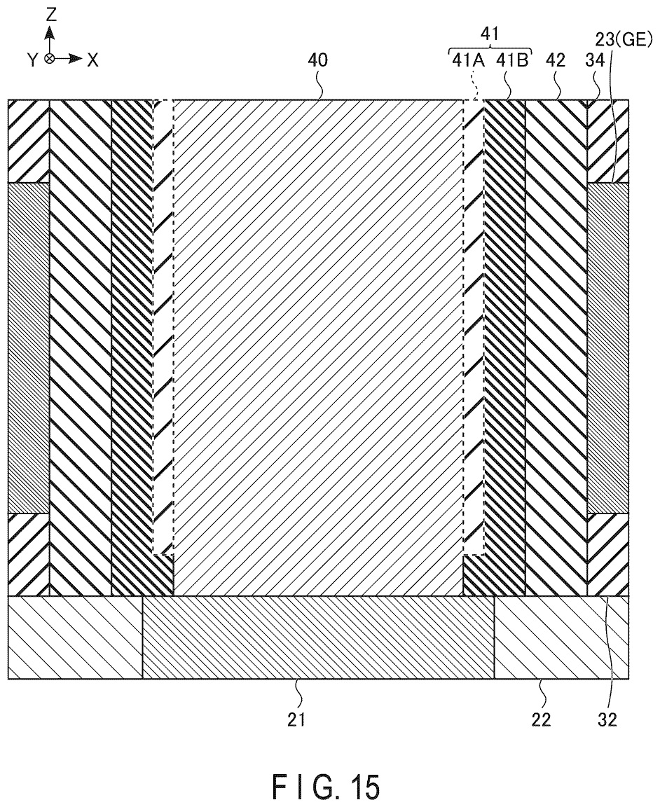

The configuration of a semiconductor device 1 according to a further example of the embodiment will be described below with reference to FIG. 15 by concentrating on differences from the configuration of the semiconductor device according to the embodiment. FIG. 15 is a sectional view illustrating an example of the structure of a gate insulating film of a transistor included in the semiconductor device according to the further example of the embodiment.

In the further example of the embodiment, the gate insulating film 41 is in contact with the lower electrode BE. With this structure, the gate insulating film 42 covers the side surface of the gate insulating film 41, and not the lower surface thereof. As in the embodiment, in the further example shown in FIG. 15, the region 41A of the gate insulating film 41 is provided from the height above the lower surface of the gate insulating film 41 to the height of the upper surface of the oxide semiconductor 40. Accordingly, the region 41A is separated from the lower electrode BE. However, no limitation is intended by this. The region 41A may be provided from the height of the lower surface of the gate insulating film 41 to the height of the upper surface of the oxide semiconductor 40. In this case, the region 41A entirely covers the side surface of the oxide semiconductor 40.

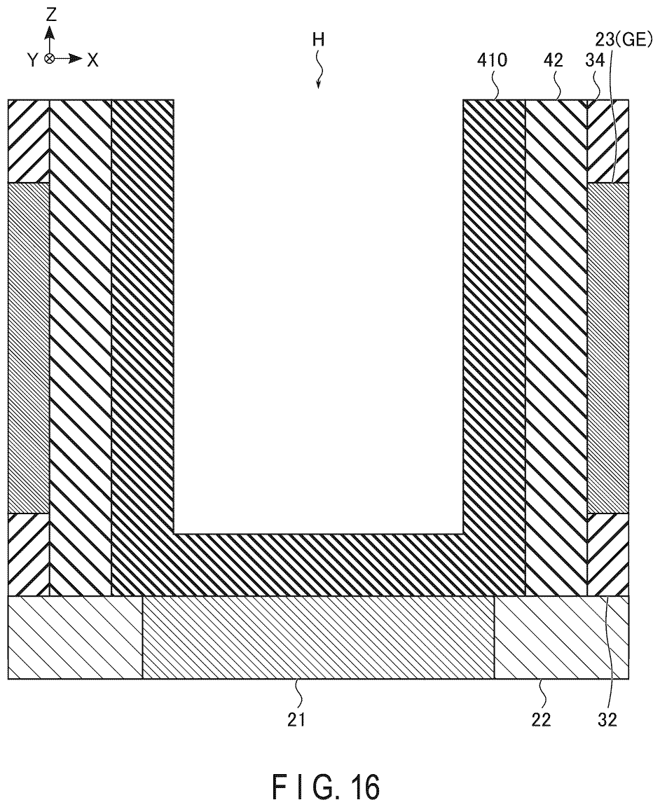

A method of manufacturing the semiconductor device 1 according to the further example of the embodiment will be described below with reference to FIG. 16 by concentrating on differences from the method of manufacturing the semiconductor device according to the embodiment. FIG. 16 is a sectional view showing an example of a method of manufacturing the semiconductor device according to the further example of the embodiment.

In the further example, in the step corresponding to FIG. 7 of the embodiment, the gate insulating film 42 is formed on the side surfaces in the hole H and then, as shown in FIG. 16, the insulator 410 is formed to cover the side surface of the gate insulating film 42 and the bottom surface in the hole H. That is, the insulator 410 is formed after the bottom portion of the insulator 420 formed in the hole H is removed. The other steps may be similar to those of the method of manufacturing the semiconductor device according to the embodiment.

The further example brings about the same effects as those of the embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first electrode;
a second electrode which is in contact with an upper surface of the first electrode;
a third electrode provided above the second electrode;
an oxide semiconductor which is in contact with an upper surface of the second electrode and which extends in a first direction from the second electrode toward the third electrode;
a first conductor provided next to the oxide semiconductor; and
a first insulating film provided between the first conductor and the oxide semiconductor,
wherein:
the first insulating film includes a first region and a second region, the second region being sandwiched between the first region and the oxide semiconductor in a second direction intersecting the first direction; and
a first concentration of nitrogen in the first region is higher than a second concentration of nitrogen in the second region.

2. The semiconductor device of claim 1, wherein the first region is provided above and apart from the second electrode.

3. The semiconductor device of claim 1, wherein the first region is provided over the entire side surface of the oxide semiconductor.

4. The semiconductor device of claim 1, wherein:
the second electrode includes a second conductor that is in contact with a lower surface of the oxide semiconductor;
the second conductor includes a third region and a fourth region, the third region being in contact with the lower surface of the oxide semiconductor, the third region being sandwiched between the fourth region and the oxide semiconductor in the first direction; and
a third concentration of nitrogen in the third region is higher than a fourth concentration of nitrogen in the fourth region.

5. The semiconductor device of claim 1, wherein:
the first insulating film further includes a fifth region, the second region being sandwiched between the first region and the fifth region in the second direction, the fifth region being in contact with the first conductor; and
a fifth concentration of nitrogen in the fifth region is higher than the first concentration.

6. The semiconductor device of claim 1, wherein the first concentration is 1×1015 atoms/cm3 or higher and 1×1018 atoms/cm3 or lower.

7. The semiconductor device of claim 1, wherein the first insulating film is so provided that nitrogen concentration gradually lowers from a side of the first region toward a side of the second region.

8. The semiconductor device of claim 1, wherein the first insulating film is an insulator including a silicon oxide, a silicon oxynitride, a metal oxide, or a metal oxynitride.

9. The semiconductor device of claim 1, further comprising a second insulating film which is in contact with a side surface of the first insulating film and the first conductor.

10. The semiconductor device of claim 9, wherein the first insulating film and the second insulating film each have a thickness of 7 nanometers or less along the second direction.

11. The semiconductor device of claim 9, wherein the second insulating film is an insulator including a silicon nitride, a metal oxide, a metal nitride, or a metal oxynitride.

12. The semiconductor device of claim 11, wherein the second insulating film comprises a monolayer film or a stacked film, the monolayer film including one layer containing a silicon nitride, a metal oxide, a metal nitride, or a metal oxynitride, the stacked film including a plurality of layers each containing a silicon nitride, a metal oxide, a metal nitride, or a metal oxynitride.

13. The semiconductor device of claim 1, wherein the first insulating film is in contact with the first conductor.

14. The semiconductor device of claim 1, wherein the oxide semiconductor contains at least one element of indium, gallium, zinc, aluminum, or tin.

15. The semiconductor device of claim 14, wherein the oxide semiconductor includes an indium-gallium-zinc oxide.

16. The semiconductor device of claim 1, wherein the first insulating film is in contact with the side surface of the oxide semiconductor in the first region.

17. The semiconductor device of claim 1, wherein the oxide semiconductor and the first insulating film constitute a vertical transistor.

18. The semiconductor device of claim 1, wherein the first electrode serves as an electrode of a capacitor.
